(19) United States
(12) Patent Application Publication
(10) Pub. No.: US 2025/0137453 A1
(43) Pub. Date: May 1, 2025

(54) INTEGRATED PUMP STATION

(71) Applicants: CCTEG BEIJING TIANMA INTELLIGENT CONTROL TECHNOLOGY CO., LTD., Beijing (CN); BEIJING CCRI-TIANMA AUTOMATION TECHNOLOGY CO., LTD., Beijing (CN)

(72) Inventors: Ran Li, Beijing (CN); Wenshu Wei, Beijing (CN); Bo Liu, Beijing (CN); Wei Wang, Beijing (CN); Hao Liu, Beijing (CN); Jian Ye, Beijing (CN); Jianqiang Wang, Beijing (CN); Chuliang Wang, Beijing (CN)

(73) Assignees: CCTEG BEIJING TIANMA INTELLIGENT CONTROL TECHNOLOGY CO., LTD., Beijing (CN); BEIJING CCRI-TIANMA AUTOMATION TECHNOLOGY CO., LTD., Beijing (CN)

(21) Appl. No.: 18/835,706

(22) PCT Filed: Feb. 21, 2022
(86) PCT No.: PCT/CN2022/077082

§ 371 Date: Aug. 2, 2024

(30) Foreign Application Priority Data
Feb. 8, 2022 (CN) 202210118850.6

(51) Int. Cl. F04B 53/08; F04B 17/03; F04B 53/16

(52) U.S. Cl. CPC F04B 53/08; F04B 17/03; F04B 53/16

(57) ABSTRACT

An integrated pump station includes: a mounting frame, a pump body, and an electric drive device. The pump body is arranged on the mounting frame; the electric drive device comprises a housing body, a motor, a frequency converter and a controller; the housing body is arranged on the mounting frame; the motor, the frequency converter and the controller are arranged in the housing body, the motor being connected to the pump body; the motor is connected to the frequency converter by means of an electric wire, the frequency converter is connected to the controller by means of an electric wire, and a water cooling pipeline of the motor, a water cooling pipeline of the frequency converter and an oil cooler of the pump body sequentially communicate with one another.

### CROSS-REFERENCE TO RELATED APPLICATION

The present application is a U.S. National Stage of International Application No. PCT/CN2022/077082, filed on Feb. 21, 2022, which claims the benefit of priority to Chinese Patent Application No. 202210118850.6, filed on Feb. 8, 2022, both of which are incorporated by reference herein in their entireties for all purposes.

### FIELD

The present disclosure relates to the field of pump bodies, and more particularly to an integrated pump station.

### BACKGROUND

Emulsion pumps are used in a coal mining face to provide a high-pressure emulsion for a hydraulic support. The emulsion pumps typically take an emulsion (95% water and 5% emulsified oil) as a medium, drive a crankshaft of a pump station by rotation of a motor, and drive a plunger to do reciprocating motion by rotation of the crankshaft to achieve liquid suction and liquid discharge. and finally output the high-pressure emulsion. The hydraulic support is extended and retracted by the support of a hydraulic cylinder driven by the high-pressure emulsion provided by the emulsion pump. At this stage, a pump head and the motor are generally coupled through a coupling. For the motor that requires frequency conversion speed regulation, an explosion-proof frequency converter is equipped, and the motor and the frequency converter are coupled by a power cable.

### SUMMARY

The integrated pump station according to embodiments of the present disclosure includes: a mounting frame; a pump body, the pump body being arranged on the mounting frame; and an electric drive device, the electric drive including a housing body, a motor, a frequency converter and a controller; the housing body being arranged on the mounting frame; the motor, the frequency converter and the controller being arranged in the housing body, the motor being coupled to the pump body, the motor being coupled to the frequency converter through an electric wire, and the frequency converter being coupled to the controller through an electric wire; and a water cooling pipeline of the motor, a water cooling pipeline of the frequency converter and an oil cooler of the pump body sequentially communicating with one another.

### BRIEF DESCRIPTION OF THE DRAWINGS

FIG. 1 is a perspective view of an integrated pump station according to an embodiment of the present disclosure.

FIG. 2 is a side view of an integrated pump station according to an embodiment of the present disclosure.

FIG. 3 is a top view of an integrated pump station according to an embodiment of the present disclosure.

FIG. 4 is a rear view of an integrated pump station according to an embodiment of the present disclosure.

### DETAILED DESCRIPTION

Embodiments of the present disclosure are described in detail below, examples of which are shown in the accompanying drawings. The following embodiments described with reference to the accompanying drawing are illustrative. It should be understood that the embodiments described are intended to explain the present disclosure, but not to limit the present disclosure.

In a related art, a split design mode of a pump station, the motor, the frequency converter and other equipment is generally adopted, and the frequency converter generally needs to occupy an equipment train separately, which lengthens the overall length of an integrated liquid supply system in a gateway area, and brings inconvenience to the advancement of a fully mechanized coal mining face. The pump station, the motor, the frequency converter and a controller are mounted and commissioned separately, and a water cooling system and a power system need to be arranged respectively, which increases the mounting cost, the overall weight and floor area of the equipment, and the maintenance cost.

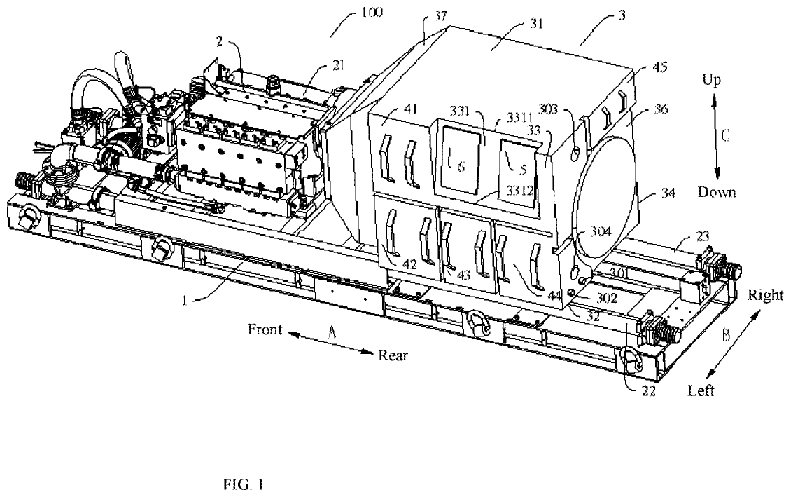

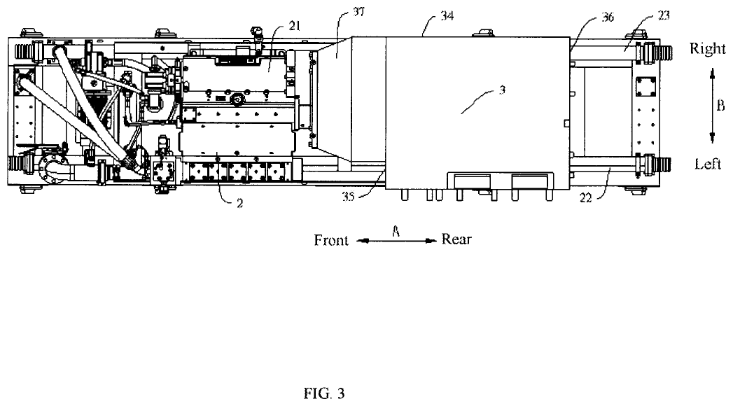

An integrated pump station 100 according to embodiments of the present disclosure is described below with reference to the accompanying drawings. As shown in FIG. 1 to FIG. 4, an integrated pump station 100 according to embodiments of the present disclosure includes a mounting frame 1, a pump body 2, and an electric drive device.

The pump body 2 is arranged on the mounting frame 1. The electric drive device includes a housing body 3, a motor, a frequency converter and a controller. The housing body 3 is arranged on the mounting frame 1. The motor, the frequency converter and the controller are arranged in the housing body 3. The motor is coupled to the pump body 2. The motor is coupled to the frequency converter through an electric wire, and the frequency converter is coupled to the controller through an electric wire. A water cooling pipeline of the motor, a water cooling pipeline of the frequency converter and an oil cooler 24 of the pump body 2 sequentially communicate with one another.

In the integrated pump station 100 according to embodiments of the present disclosure, the pump body 2 and the housing body 3 are arranged on the mounting frame 1, and the motor, the frequency converter and the controller are arranged in the housing body 3, so that the motor. the frequency converter and the controller are integrated on the mounting frame 1 by the housing body 3, that is, the mounting frame 1 is provided with the pump body 2, the motor, the frequency converter, and the controller. Therefore, only one equipment train is needed to carry the integrated pump station 100 according to embodiments of the present disclosure, and the frequency converter inside the integrated pump station 100 does not need to occupy another equipment train, thus it is convenient for the equipment train to drive the integrated pump station 100 to move in a roadway.

Furthermore, the water cooling pipeline of the motor, the water cooling pipeline of the frequency converter and the oil cooler 24 of the pump body 2 sequentially communicate with one another, therefore, it just needs to communicate one external water inlet pipe with the water cooling pipeline of the motor and communicate one external water outlet pipe with the oil cooler 24 of the pump body 2 to complete circulation of cooling water in a water-cooled system of the integrated pump station 100. There is no need to separately provide the external water inlet pipe and the external water outlet pipe for each part (the pump body 2, the motor and the frequency converter), thereby reducing the number of the external water inlet pipes and the number of the external water outlet pipes, further increasing integration degree of the integrated pump station 100, and improving the convenience of the integrated pump station 100, so that the integrated pump station 100 occupies small space when in use and is suitable for a place with narrow space. The water cooling pipeline of the motor, the water cooling pipeline of the frequency converter, and the oil cooler 24 of the pump body 2 sequentially communicate with one another, which may also allow the cooling water to cool the motor, the frequency converter, and the oil cooler of the pump body 2 in sequence. The heat generation of the motor is greater than that of the frequency converter and the pump body 2, and a priority of motor cooling is higher. The frequency converter and the oil cooler of the pump body 2 is cooled after the motor is cooled, which may facilitate the smooth operation of the integrated pump station 100 and meet the cooling requirement of the integrated pump station 100.

Therefore, the integrated pump station 100 according to embodiments of the present disclosure has the advantage of high integration, high convenience, small space occupation and facilitating movement in the roadway.

As shown in FIG. 1 to FIG. 4, the integrated pump station 100 according to embodiments of the present disclosure includes the mounting frame 1, the pump body 2, and the electric drive device.

The pump body 2 is arranged on the mounting frame 1. Specifically, the mounting frame 1 is provided with a suction pipe 22 and a discharge pipe 23 fitted with the pump body 2, and an extension direction of the suction pipe 22 and an extension direction of the discharge pipe 23 are consistent with a length direction of the mounting frame 1. For example, the length direction of the mounting frame 1 is a front-and-rear direction, and the extension direction of the suction pipe 22 and the extension direction of the discharge pipe 23 are the front-and-rear direction. The front-and-rear direction is shown by an arrow A in figures.

The electric drive device includes the housing body 3, the motor, the frequency converter, and the controller, and the housing body 3 is arranged on the mounting frame 1.

As shown in FIG. 1 to FIG. 4, in some embodiments, the housing body 3 includes a top plate 31, a bottom plate 32, a first side plate 33, a second side plate 34, a third side plate 35, and a fourth side plate 36. The top plate 31 and the bottom plate 32 are oppositely arranged in an up-and-down direction, the first side plate 33 and the second side plate 34 are oppositely arranged in a first direction, and the third side plate 35 and the fourth side plate 36 are oppositely arranged in a second direction. Any two of the up-and-down direction, the first direction, and the second direction are perpendicular to each other. The first direction may be a left-and-right direction, and the second direction may be the front-and-rear direction. The left-and-right direction is shown by an arrow B in figures, and the up-and-down direction is shown by an arrow C in figures. For example, the top plate 31 is located above the bottom plate 32, and the bottom plate 32 is arranged on the mounting frame 1; and the first side plate 33 is located on a left side of the second side plate 34, and the third side plate 35 is located on a front side of the fourth side plate 36.

The motor, the frequency converter and the controller are arranged in the housing body 3, and the motor is coupled to the pump body 2, so that the motor provides power for the pump body 2. The motor is coupled to the frequency converter through an electric wire, and the frequency converter is coupled to the controller through the electric wire, so that the frequency converter and the controller cooperate with the motor, to control the start/stop and the rotational speed of the motor.

Specifically, the housing body 3 is located at a rear side of the pump body 2, a protective cover 37 is provided on the third side plate 35 of the housing body 3, and an output shaft of the motor passes through the third side plate 35 and extends into the protective cover 37 and is coupled to the pump body 2. The pump body 2 includes a crankshaft, a crankcase 21, and a coupling. Part of the coupling is located in the protective cover 7, and the coupling has a first end coupled to the crankshaft and a second end coupled to the output shaft of the motor. The frequency converter may control the rotational speed of the output shaft of the motor, so there is no need to equip a speed reducer, thereby improving the transmission efficiency of the output shaft of the motor. The weight of a transmission part may be reduced without the speed reducer, and the probability of damage to the transmission part may also be reduced.

The water cooling pipeline of the motor, the water cooling pipeline of the frequency converter. and the oil cooler 24 of the pump body 2 sequentially communicate with one another.

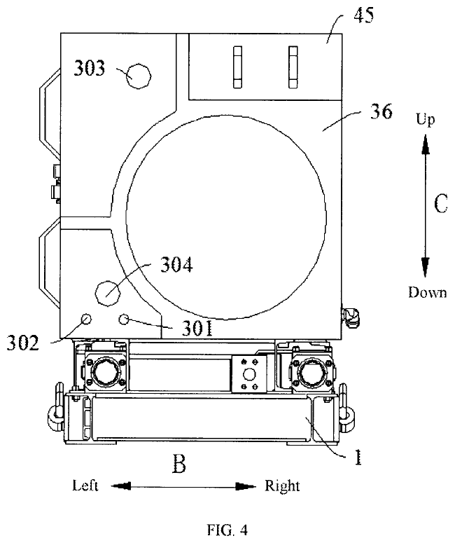

As shown in FIG. 1 and FIG. 4, in some embodiments, the housing body 3 has a cooling water inlet 301 and a cooling water outlet 302. The water cooling pipeline of the motor is attached to a body of the motor in order to cool down the body of the motor, and the water cooling pipeline of the motor has a first water inlet and a first water outlet. The frequency converter includes a variable frequency motor, and the water cooling pipeline of the frequency converter is attached to the variable frequency motor, so that the water cooling pipeline of the frequency converter is convenient for cooling the variable frequency motor. The water cooling pipeline of the frequency converter has a second water inlet and a second water outlet. The pump body 2 includes an oil tank and the oil cooler 24, the oil cooler 24 is attached to the oil tank, so that it is convenient for the oil cooler 24 to cool the oil tank (an oil inside the oil tank). The oil cooler 24 includes a third water inlet and a third water outlet 241.

The first water inlet is communicated with the cooling water inlet 301, the second water inlet is communicated with the first water outlet, the third water inlet is communicated with the second water outlet, and the third water outlet 241 is communicated with the cooling water outlet 302, so that the water cooling pipeline of the motor, the water cooling pipeline of the frequency converter and the oil cooler 24 of the pump body 2 sequentially communicate with one another. The water cooling pipeline of the motor, the water cooling pipeline of the frequency converter and the oil cooler 24 of the pump body 2 sequentially communicate with one another, so that the housing body 3 does not need to be provided with a plurality of water inlets and a plurality of water outlets, and only needs to be provided with one cooling water inlet 301 and one cooling water outlet 302, to meet the requirements of the water cooling system. That is, only one external water inlet pipe and one external water outlet pipe is needed, which may meet the requirements of the water cooling system, thereby increasing the integration and convenience of the integrated pump station 100.

The cooling water inlet 301 and the cooling water outlet 302 are defined in a same side plate of the housing body 3, so that the space occupied by the external water inlet pipe and the external water outlet pipe may be reduced when they are respectively fitted in the cooling water inlet 301 and the cooling water outlet 302, and the water cooling pipeline of the motor, the water cooling pipeline of the frequency converter and part of pipelines in the oil cooler 24 of the pump body 2 are located inside the housing body 3, thus it is not easy to be damaged. Specifically, the cooling water inlet 301 and the cooling water outlet 302 are defined in the fourth side plate 36. That is, The cooling water inlet 301 and the cooling water outlet 302 are arranged at an end of the housing body 3 away from the pump body 2, so that the cooling water pipe does not increase occupied space in the first direction when fitted in the cooling water inlet 301 and the cooling water outlet 302, thus it convenient for the integrated pump station 100 to be suitable for the narrow space. For example, The cooling water inlet 301 and the cooling water outlet 302 are arranged at a rear end part of the housing body 3, so that the cooling water pipe does not increase occupied space in the left-and-right direction when fitted in the cooling water inlet 301 and the cooling water outlet 302, thus it convenient for the integrated pump station 100 to be suitable for the narrow space.

The cooling water inlet 301 and the cooling water outlet 302 are located at a lower end part of the fourth side plate 36, so that a water droplet leaked from the cooling water inlet 301 and the cooling water outlet 302 will not drip onto a component of the integrated pump station 100, thereby preventing the water droplet damaging the component of the integrated pump station 100.

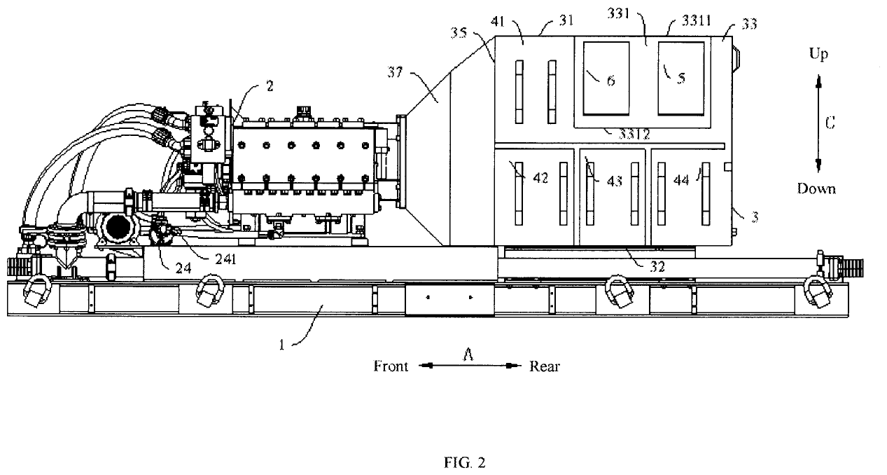

As shown in FIG. 1 and FIG. 2, in some embodiments, the housing body 3 has a plurality of explosion-proof chambers, and an inlet of the explosion-proof chamber is defined in the first side plate 33, the first side plate 33 is provided with a plurality of explosion-proof chamber doors, and the plurality of explosion-proof chamber doors cover the plurality of explosion-proof chambers by one-to-one correspondence. The frequency converter includes a plurality of modules, and the plurality of modules is detachably mounted in the plurality of explosion-proof chambers by one-to-one correspondence. That is, each module is arranged in one explosion-proof chamber, the modules are coupled through an industrial bus, and each of the plurality of modules is arranged in different explosion-proof chambers, so that each module may be disassembled and assembled separately, thereby improving the convenience of maintenance and equipment safety.

As shown in FIG. 1 and FIG. 2, in some embodiments, the explosion-proof chambers include a first explosion-proof chamber, a second explosion-proof chamber, a third explosion-proof chamber, and a fourth explosion-proof chamber. A first explosion-proof chamber door 41 covering the first explosion-proof chamber, a second explosion-proof chamber door 42 covering the second explosion-proof chamber, a third explosion-proof chamber door 43 covering the third explosion-proof chamber, and a fourth explosion-proof chamber door 44 covering the fourth explosion-proof chamber are provided on the first side plate 33.

The frequency converter includes a filter module, a charging unit module, a DC (direct current) rectifier unit module, and an inverter unit module. The filter module is detachably arranged in the first explosion-proof chamber, the charging unit module is detachably arranged in the second explosion-proof chamber, the DC rectifier unit module is detachably arranged in the third explosion-proof chamber, and the inverter unit module is detachably arranged in the fourth explosion-proof chamber. The frequency converter is divided into the filter module, the charging unit module, the DC rectifier unit module, and the inverter unit module, so that the modules may be disassembled independently, to facilitate the mounting and maintenance of the frequency converter.

As shown in FIG. 1 and FIG. 2, in some embodiments, the controller includes a control panel 5, the control panel 5 is arranged on the first side plate 33, and the control panel 5 is provided with a control button and a control display screen. Therefore, the control button may be used to control the motor, and the operation of the motor may be observed through the control display screen.

The frequency converter includes a frequency conversion panel 6, the frequency conversion panel 6 is arranged on the first side panel 33, and the frequency conversion panel 6 is provided with a frequency conversion button and a frequency conversion display screen. The working parameter and working condition of the frequency converter may be observed through the frequency conversion display screen, and the working parameter of the frequency converter may be directly changed through the frequency conversion button, thereby improving the convenience of changing the working parameter of the frequency converter.

As shown in FIG. 1 and FIG. 2, in some embodiments, the first side plate 33 includes an inclined part 331 facing upwards, and an upper edge 3311 of the inclined part 331 is adjacent to the second side plate in the first direction relative to a lower edge 3312 of the inclined part 331. The control panel 5 and the frequency conversion panel 6 are arranged on the inclined part. Specifically, the housing body 3 has a through hole inclined upwards, and the through hole runs through the first side plate 33 and the top plate 31. A bottom wall of the through hole is located on the first side plate 33 and adjacent to a side of the top plate 31, and a top wall of the through hole is located on the top plate 31 and adjacent to a side of the first side plate 33. The lower edge 3312 of the inclined part 331 is coupled to the bottom wall of the through hole, and the upper edge 3311 of the inclined part 331 is coupled to the top wall of the through hole. The control panel 5 and the frequency conversion panel 6 are located on the inclined part 331 facing upwards, so that the control panel 5 and the frequency conversion panel 6 is in a more comfortable viewing angle and operating position for the human body, thus it is convenient for a staff to observe the control display screen and the frequency conversion display screen and to operate the control button and the frequency conversion button.

The inclined part 331 and the inlet of the first explosion-proof chamber are located above the inlet of the second explosion-proof chamber, an inlet of the third explosion-proof chamber, and an inlet of the fourth explosion-proof chamber. Specifically, the inclined part 331 is located in an upper half of the first side plate 33, the inlet of the first explosion-proof chamber is defined in the upper half of the first side plate 33, and the inlet of the second explosion-proof chamber, the inlet of the third explosion-proof chamber, and the inlet of the fourth explosion-proof chamber are defined in a lower half of the first side plate 33. Thus the plurality of explosion-proof chambers may be more compactly located in the housing body 3, and the integration of the integrated pump station 100 is increased. For example, the inclined part 331 is located on a rear side of the first explosion-proof chamber, the control panel 5 and the frequency conversion panel 6 are arranged in the front-and-rear direction, and the control panel 5 is located on a rear side of the frequency conversion panel 6.

As shown in FIG. 1 and FIG. 4, in some embodiments, the housing body 3 has a cable input port 303 and a cable output port 304, an input plug is arranged on the cable input port 303, and an output plug is arranged on the cable output port 304. The frequency converter is coupled to the motor in series, and is coupled in parallel with the controller and an oil pump motor of the pump body between the input plug and the output plug. Therefore, it is only necessary to define one cable input port 303 and one cable output port 304 in the housing body 3, arrange one input plug on the cable input port 303 and arrange one output plug on the cable output port 304, to meet the power supply for the motor, the frequency converter, the controller, and the oil pump motor of the pump body 2. Only one cable input port 303 and one cable output port 304 need to be defined in the housing body 3, which may reduce the number of external cables, reduce the space occupied by the external cables and increase the integration of the integrated pump station 100. Specifically, the input plug is coupled to an output end of the frequency converter through a wiring, and the output end of the frequency converter is coupled to an output end of the motor. The input plug is coupled to an input end of the controller through a wiring, the input plug is coupled to an input end of the oil pump motor of the pump body 2 through a wiring, and the output end of the oil pump motor is coupled to the output plug.

As shown in FIG. 1 and FIG. 4, in some embodiments, the cable input port 303 is defined in an upper part of the fourth side plate 36, and the cable output port 304 is defined in a lower part of the fourth side plate 36. The housing body 3 has a wiring chamber, an opening of the wiring chamber is defined in the upper part of the fourth side plate 36, and the fourth side plate 36 is provided with a wiring chamber door 45 covering the opening of the wiring chamber. A wiring terminal of the frequency converter and the controller is provided in the wiring chamber, and the cable input port 303 and the opening of the wiring chamber are defined in the upper part of the fourth side plate 36 for easy wiring, thereby facilitating the electrical connection of the frequency converter and the controller with a pump body circuit.

The cable input port 303 and the cable output port 304 are defined in the fourth side plate 36, that is, the cable input port 303 and the cable output port 304 are defined in the end of the housing body 3 away from the pump body 2, so that the external cable does not increase occupied space in the first direction when fitted in the input plug and the output plug, thus it easy for the integrated pump station 100 to move in the second direction. For example, the cable input port 303 and the cable output port 304 are defined in the rear end part of the housing body 3, so that the external cable will not increase the occupied space in the left-and-right direction when fitted in the input plug and the output plug.

The integrated pump station according to embodiments of the present disclosure includes: a mounting frame; a pump body, the pump body being arranged on the mounting frame; and an electric drive device, the electric drive including a housing body, a motor, a frequency converter and a controller; the housing body being arranged on the mounting frame; the motor, the frequency converter and the controller being arranged in the housing body, the motor being coupled to the pump body, the motor being coupled to the frequency converter through an electric wire, and the frequency converter being coupled to the controller through an electric wire; and a water cooling pipeline of the motor, a water cooling pipeline of the frequency converter and an oil cooler of the pump body sequentially communicating with one another.

In some embodiments, the housing body has a cooling water inlet and a cooling water outlet, and the cooling water inlet and the cooling water outlet are defined in a same side plate of the housing body; the water cooling pipeline of the motor has a first water inlet and a first water outlet, and the first water inlet is communicated with the cooling water inlet; the frequency converter includes a variable frequency motor, the water cooling pipeline of the frequency converter is attached to the variable frequency motor, the water cooling pipeline of the frequency converter has a second water inlet and a second water outlet, and the second water inlet is communicated with the first water outlet; and the pump body includes an oil tank and the oil cooler, the oil cooler is attached to the oil tank, the oil cooler includes a third water inlet and a third water outlet, the third water inlet is communicated with the second water outlet, and the third water outlet is communicated with the cooling water outlet.

In some embodiments, the housing body includes a top plate, a bottom plate, a first side plate, a second side plate, a third side plate, and a fourth side plate; the top plate and the bottom plate are oppositely arranged in an up-and-down direction, the first side plate and the second side plate are oppositely arranged in a first direction, the third side plate and the fourth side plate are oppositely arranged in a second direction, and any two of the up-and-down direction, the first direction, and the second direction are perpendicular to each other; and an output shaft of the motor passes through the third side plate and is coupled to the pump body, and the cooling water inlet and the cooling water outlet are defined in the fourth side plate.

In some embodiments, the housing body has a plurality of explosion-proof chambers, an inlet of the explosion-proof chamber is defined in the first side plate, the first side plate is provided with a plurality of explosion-proof chamber doors, and the plurality of explosion-proof chamber doors cover the plurality of explosion-proof chambers by one-to-one correspondence; and the frequency converter includes a plurality of modules, and the plurality of modules is detachably mounted in the plurality of explosion-proof chambers by one-to-one correspondence.

In some embodiments, the explosion-proof chambers include a first explosion-proof chamber, a second explosion-proof chamber, a third explosion-proof chamber, and a fourth explosion-proof chamber; a first explosion-proof chamber door covering the first explosion-proof chamber, a second explosion-proof chamber door covering the second explosion-proof chamber, a third explosion-proof chamber door covering the third explosion-proof chamber, and a fourth explosion-proof chamber door covering the fourth explosion-proof chamber are provided on the first side plate; and the frequency converter includes a filter module, a charging unit module, a DC rectifier unit module, and an inverter unit module; the filter module is detachably arranged in the first explosion-proof chamber, the charging unit module is detachably arranged in the second explosion-proof chamber, the DC rectifier unit module is detachably arranged in the third explosion-proof chamber, and the inverter unit module is detachably arranged in the fourth explosion-proof chamber.

In some embodiments, the controller includes a control panel, the control panel is arranged on the first side plate, and the control panel is provided with a control button and a control display screen; and the frequency converter includes a frequency conversion panel, the frequency conversion panel is arranged on the first side panel, and the frequency conversion panel is provided with a frequency conversion button and a frequency conversion display screen.

In some embodiments, the first side plate includes an inclined part facing upwards, an upper edge of the inclined part is adjacent to the second side plate in the first direction relative to a lower edge of the inclined part, and the control panel and the frequency conversion panel are arranged on the inclined part; and the inclined part and the inlet of the first explosion-proof chamber are located above the inlet of the second explosion-proof chamber, an inlet of the third explosion-proof chamber, and an inlet of the fourth explosion-proof chamber.

In some embodiments, the pump body includes a crankshaft and a coupling; and the coupling has a first end coupled to the crankshaft and a second end coupled to the output shaft of the motor.

In some embodiments, the housing body has a cable input port and a cable output port, an input plug is arranged on the cable input port, and an output plug is arranged on the cable output port; and the frequency converter is coupled to the motor in series, and is coupled in parallel with the controller and an oil pump motor of the pump body between the input plug and the output plug.

In some embodiments, the cable input port is defined in an upper part of the fourth side plate, and the cable output port is defined in a lower part of the fourth side plate; and the housing body has a wiring chamber, an opening of the wiring chamber is defined in the upper part of the fourth side plate, and the fourth side plate is provided with a wiring chamber door covering the opening of the wiring chamber.

In the description of the present disclosure, it should be understood that the orientation or position relationship indicated by the terms “center”, “longitudinal”, “transverse”, “length”, “width”. “thickness”, “up”, “down”, “front”, “rear”, “left”, “right”, “vertical”, “horizontal”, “top”, “bottom”, “inner”, “outer”, “clockwise”, “counterclockwise”, “axial”, “radial” and “circumferential” and the like, is based on the orientation or position relationship shown in the accompanying drawings, which is only for the convenience of describing the present disclosure and simplifying the description, and does not indicate or imply that the referred device or element must have a specific orientation, and be constructed and operated in a specific orientation, so it cannot be understood as a limitation of the present disclosure.

In addition, the terms “first” and “second” are only used for purpose of description, and cannot be understood as indicating or implying relative importance or implicitly indicating the number of indicated technical features. Therefore, the feature defined as “first” or “second” may explicitly or implicitly include at least one such feature. In the description of the present disclosure, “a plurality of” means at least two, such as two, three, etc., unless otherwise specifically defined.

In the present disclosure, unless otherwise expressly defined, terms such as “mount”, “couple”, “connect”, “fix” shall be understood broadly, and may be, for example, fixed connections, detachable connections, or integral connections; may also be mechanical or electrical connections or intercommunication; may also be direct connections or indirect connections via intervening media; may also be inner communications or interactions of two elements, unless otherwise specifically defined. For those skilled in the art, the specific meaning of the above terms in the present disclosure may be understood according to the specific situations.

In the present disclosure, unless otherwise expressly defined, the first feature “below”, “under”, “on bottom of”, “above”, “on”, or “on top of” a second feature may include an embodiment in which the first feature is in direct contact with the second feature, or the first feature is in indirect contact with the second feature through an intermediate media. And, the first feature “above”, “on”, or “on top of” a second feature may include an embodiment in which the first feature is right or obliquely “above”, “on”, or “on top of” the second feature, or just means that the first feature is at a height higher than that of the second feature. A first feature “below”, “under”, or “on bottom of” a second feature may include an embodiment in which the first feature is right or obliquely “below”, “under”, or “on bottom of” the second feature, or just means that the first feature is at a height lower than that of the second feature.

In the description of the present disclosure, terms such as “an embodiment”, “some embodiments”, “an example”, “a specific example” or “some examples” means that a particular feature, structure, material, or characteristic described in connection with the embodiment or example is included in at least one embodiment or example of the present disclosure. Thus, the appearances of these terms in various places throughout this specification are not necessarily referring to the same embodiment or example of the present disclosure. Furthermore, the particular features, structures, materials, or characteristics may be combined in any suitable manner in one or more embodiments or examples. In addition, without contradiction, those skilled in the art may combine and unite different embodiments or examples or features of the different embodiments or examples described in this specification.

Although the embodiments of the present disclosure have been shown and described above, it may be understood that the above embodiments are illustrative and shall not be understood as limitation to the present disclosure, and changes, modifications, alternatives and variations may be made in the above embodiments within the scope of the present disclosure by those skilled in the art.

1. An integrated pump station, comprising:
a mounting frame;
a pump body, the pump body being arranged on the mounting frame; and
an electric drive device, the electric drive comprising a housing body, a motor, a frequency converter and a controller; the housing body being arranged on the mounting frame; the motor, the frequency converter and the controller being arranged in the housing body, the motor being coupled to the pump body, the motor being coupled to the frequency converter through an electric wire, and the frequency converter being coupled to the controller through an electric wire; and a water cooling pipeline of the motor, a water cooling pipeline of the frequency converter and an oil cooler of the pump body sequentially communicating with one another.

2. The integrated pump station according to claim 1, wherein
the housing body has a cooling water inlet and a cooling water outlet, and the cooling water inlet and the cooling water outlet are defined in a same side plate of the housing body;
the water cooling pipeline of the motor has a first water inlet and a first water outlet, and the first water inlet is communicated with the cooling water inlet;
the frequency converter comprises a variable frequency motor, the water cooling pipeline of the frequency converter is attached to the variable frequency motor, the water cooling pipeline of the frequency converter has a second water inlet and a second water outlet, and the second water inlet is communicated with the first water outlet; and
the pump body comprises an oil tank and the oil cooler, the oil cooler is attached to the oil tank, the oil cooler comprises a third water inlet and a third water outlet, the third water inlet is communicated with the second water outlet, and the third water outlet is communicated with the cooling water outlet.

3. The integrated pump station according to claim 2, wherein the housing body comprises a top plate, a bottom plate, a first side plate, a second side plate, a third side plate, and a fourth side plate; the top plate and the bottom plate are oppositely arranged in an up-and-down direction, the first side plate and the second side plate are oppositely arranged in a first direction, the third side plate and the fourth side plate are oppositely arranged in a second direction, and any two of the up-and-down direction, the first direction, and the second direction are perpendicular to each other; and wherein an output shaft of the motor passes through the third side plate and is coupled to the pump body, and the cooling water inlet and the cooling water outlet are defined in the fourth side plate.

4. The integrated pump station according to claim 3, wherein the housing body has a plurality of explosion-proof chambers, an inlet of the explosion-proof chamber is defined in the first side plate, the first side plate is provided with a plurality of explosion-proof chamber doors, and the plurality of explosion-proof chamber doors cover the plurality of explosion-proof chambers by one-to-one correspondence; and
the frequency converter comprises a plurality of modules, and the plurality of modules is detachably mounted in the plurality of explosion-proof chambers by one-to-one correspondence.

5. The integrated pump station according to claim 4, wherein
the explosion-proof chambers comprise a first explosion-proof chamber, a second explosion-proof chamber, a third explosion-proof chamber, and a fourth explosion-proof chamber; a first explosion-proof chamber door covering the first explosion-proof chamber, a second explosion-proof chamber door covering the second explosion-proof chamber, a third explosion-proof chamber door covering the third explosion-proof chamber, and a fourth explosion-proof chamber door covering the fourth explosion-proof chamber are provided on the first side plate; and
the frequency converter comprises a filter module, a charging unit module, a DC rectifier unit module, and an inverter unit module; the filter module is detachably arranged in the first explosion-proof chamber, the charging unit module is detachably arranged in the second explosion-proof chamber, the DC rectifier unit module is detachably arranged in the third explosion-proof chamber, and the inverter unit module is detachably arranged in the fourth explosion-proof chamber.

6. The integrated pump station according to claim 5, wherein
the controller comprises a control panel, the control panel is arranged on the first side plate, and the control panel is provided with a control button and a control display screen; and
the frequency converter comprises a frequency conversion panel, the frequency conversion panel is arranged on the first side panel, and the frequency conversion panel is provided with a frequency conversion button and a frequency conversion display screen.

7. The integrated pump station according to claim 6, wherein the first side plate comprises an inclined part facing upwards, an upper edge of the inclined part is adjacent to the second side plate in the first direction relative to a lower edge of the inclined part, and the control panel and the frequency conversion panel are arranged on the inclined part; and
the inclined part and the inlet of the first explosion-proof chamber are located above the inlet of the second explosion-proof chamber, an inlet of the third explosion-proof chamber, and an inlet of the fourth explosion-proof chamber.

8. The integrated pump station according to claim 3, wherein the pump body comprises a crankshaft and a coupling, and the coupling has a first end coupled to the crankshaft and a second end coupled to the output shaft of the motor.

9. The integrated pump station according to claim 3, wherein
the housing body has a cable input port and a cable output port, an input plug is arranged on the cable input port, and an output plug is arranged on the cable output port; and the frequency converter is coupled to the motor in series, and is coupled in parallel with the controller and an oil pump motor of the pump body between the input plug and the output plug.

10. The integrated pump station according to claim 9, wherein
the cable input port is defined in an upper part of the fourth side plate, and the cable output port is defined in a lower part of the fourth side plate; and
the housing body has a wiring chamber, an opening of the wiring chamber is defined in the upper part of the fourth side plate, and the fourth side plate is provided with a wiring chamber door covering the opening of the wiring chamber.

11. The integrated pump station according to claim 1, wherein the mounting frame is provided with a suction pipe and a discharge pipe fitted with the pump body, and an extension direction of the suction pipe and an extension direction of the discharge pipe are consistent with a length direction of the mounting frame.

12. The integrated pump station according to claim 3, wherein the first direction is a left-and-right direction, and the second direction is a front-and-rear direction;
the top plate is located above the bottom plate, and the bottom plate is arranged on the mounting frame; and
the first side plate is located on a left side of the second side plate, and the third side plate is located on a front side of the fourth side plate.

13. The integrated pump station according to claim 12, wherein the housing body is located at a rear side of the pump body, a protective cover is provided on the third side plate of the housing body, and an output shaft of the motor passes through the third side plate and extends into the protective cover and is coupled to the pump body.

14. The integrated pump station according to claim 12, wherein the cooling water inlet and the cooling water outlet are arranged at a rear end part of the housing body.

15. The integrated pump station according to claim 3, wherein the cooling water inlet and the cooling water outlet are located at a lower end part of the fourth side plate.

16. The integrated pump station according to claim 3, wherein the plurality of modules are coupled through an industrial bus.

17. The integrated pump station according to claim 6, wherein the second direction is a front-and-rear direction, the inclined part is located on a rear side of the first explosion-proof chamber, the control panel and the frequency conversion panel are arranged in the front-and-rear direction, and the control panel is located on a rear side of the frequency conversion panel.

18. The integrated pump station according to claim 7, wherein the housing body has a through hole inclined upwards, and the through hole runs through the first side plate and the top plate;
a bottom wall of the through hole is located on the first side plate and adjacent to a side of the top plate, and a top wall of the through hole is located on the top plate and adjacent to a side of the first side plate; and
the lower edge of the inclined part is coupled to the bottom wall of the through hole, and the upper edge of the inclined part is coupled to the top wall of the through hole.

19. The integrated pump station according to claim 7, wherein the inclined part is located in an upper half of the first side plate, the inlet of the first explosion-proof chamber is defined in the upper half of the first side plate, and the inlet of the second explosion-proof chamber, the inlet of the third explosion-proof chamber, and the inlet of the fourth explosion-proof chamber are defined in a lower half of the first side plate.

20. The integrated pump station according to claim 10, wherein a wiring terminal of the frequency converter and the controller is provided in the wiring chamber.
